(19) United States
(12) Patent Application Publication
(10) Pub. No.: US 2013/0275067 A1
(43) Pub. Date: Oct. 17, 2013

(54) STATE OF CHARGE ERROR CORRECTION SYSTEMS AND METHODS

(71) Applicant: QUALCOMM INNOVATION CENTER, INC., San Diego, CA (US)

(72) Inventors: Eric I. Mikuteit, San Diego, CA (US); Todd R. Sutton, San Diego, CA (US); James P. Stump, San Diego, CA (US); Abhijeet V. Dharmapurikar, San Diego, CA (US); Bobby M. Sadsad, San Diego, CA (US); Jungim Kim, San Diego, CA (US)

(73) Assignee: QUALCOMM INNOVATION CENTER, INC., San Diego, CA (US)

(21) Appl. No.: 13/747,619

(22) Filed: Jan. 23, 2013

Related U.S. Application Data
(60) Provisional application No. 61/623,040, filed on Apr. 11, 2012.

(51) Int. Cl. G01R 31/36; G06F 17/00

(52) U.S. Cl. CPC G01R 31/3606; G06F 17/00
USPC 702/63

(57) ABSTRACT

Systems and methods for determining a state of charge of a battery on a mobile device are disclosed. An exemplary method may include obtaining, when the battery is applying a level of current below a threshold level, an initial state of charge of the battery based upon a measured open circuit voltage value that is applied by the battery. Charge drawn from, and provided to, the battery is monitored from a time after the measured open circuit voltage value is obtained and a state of charge value is calculated when the battery is loaded after the initial open circuit voltage value is obtained based upon the monitored charge. An estimated open circuit voltage for the battery is calculated based upon simultaneous measurements of battery voltage and battery current, and a corrected state of charge value is generated using the estimated open circuit voltage.

### CLAIM OF PRIORITY UNDER 35 U.S.C. §119

The present Application for Patent claims priority to Provisional Application No. 61/623,040 entitled “State of Charge Error Correction Systems and Methods” filed Apr. 30, 2012, and assigned to the assignee hereof and hereby expressly incorporated by reference herein.

### BACKGROUND

1. Field

The present invention relates generally to power systems on mobile communication devices, and more specifically to determining a state of charge of a battery on a mobile communication device.

2. Background

Mobile communication devices such as smartphones, tablet computers, gaming devices, and laptop computers are now ubiquitous. A common and ongoing issue with these types of devices is power management. More specifically, these types of devices continue to develop more advanced processing resources, displays, and communication systems that demand more and more power.

These various loads (e.g., the display, processors, communication components, etc.) can quickly drain a battery of a mobile communication device, and from a user's perspective, it is very undesirable for a communication device to completely lose power, and it is especially undesirable for the user to be surprised by a low power condition that renders the user unable to use the communication device.

As a consequence, mobile communication devices typically have, at least, a rudimentary battery monitoring system (BMS) to calculate the state of charge (SOC) of the battery and provide the user with feedback about the remaining battery life. In many instances this reporting is provided graphically as bar-type display in a user interface that changes size in relation to the state of charge remaining (e.g., percentage of remaining capacity) in the battery of the mobile communication device. When the state of charge is at a high level (e.g., the battery is completely charged), for example, the bar is full length, and as the state of charge of the battery decreases, the bar decreases in size. In this way, the user is able to respond to a low state of charge condition by charging the mobile communication device or reducing the use of one or more subsystems of the mobile communication device.

In addition, the state of charge information is utilized by under voltage lockout (UVLO) components of the mobile device that turn off power to other components of the mobile device to prevent low voltages from potentially damaging voltage-sensitive circuitry of the mobile device.

Unfortunately, the typical approaches for determining the state of charge of a battery are prone to errors that render the state of charge estimate unreliable; thus, the corresponding subsystems (e.g., bar-type user indicator and UVLO systems) that rely on the state of charge calculation may be inaccurate or not operate as expected. As a consequence, users are often surprised to find that the battery of their mobile device is unable to apply enough power for the user to perform an important function such as making a phone call or accessing the Internet. Thus, the current approaches to estimating the state-of-charge of a battery are less than optimal and often lead to an unfavorable user-experience.

### SUMMARY

Some aspects of the present invention may be characterized as a method for determining a state of charge of a battery on a mobile device. The method may include obtaining, when the battery is applying a level of current below a threshold level, an initial state of charge of the battery based upon a measured open circuit voltage value that is applied by the battery. In addition, the charge drawn from, and provided to, the battery may be monitored from a time after the measured open circuit voltage value is obtained. A loaded state of charge value may then be calculated when the battery is loaded after the initial open circuit voltage value is obtained based upon the monitored charge. An estimated open circuit voltage for the battery may then be calculated based upon simultaneous measurements of battery voltage and battery current, and a corrected state of charge value is generated using the estimated open circuit voltage.

Other aspects may be characterized as a device for determining a state of charge of a battery. The device may include a voltage monitor component to provide an indication of a voltage of the battery and a charge monitor component to provide an indication of charge drawn from, and provided to, the battery. In addition, the device may include a collection of characterization data that includes battery data that defines a battery curve that maps open circuit voltage values of the battery to state of charge values for the battery. A state of charge (SOC) component of the device obtains, using the characterization data, a state of charge value of the battery for a measured open circuit voltage (OCV) and estimates a loaded state of charge of the battery when the battery is loaded by adjusting the state of charge value based upon the charge drawn from, and provided to, the battery. An SOC error correction component of the device reduces errors in the loaded state of charge value using an estimated open circuit voltage that is calculated from simultaneous readings of the voltage and current of the battery.

### BRIEF DESCRIPTION OF THE DRAWINGS

FIG. 1 is a is a block diagram depicting an exemplary mobile device;

FIG. 2 is a graph illustrating battery charge versus battery voltage for an exemplary battery;

FIG. 3 includes graphs depicting a state of charge relative to a Coulomb count during an exemplary mode of operation;

FIG. 4 is a block diagram depicting an embodiment of the battery monitoring system depicted in FIG. 1;

FIG. 5 is a flowchart depicting a method for determining a state of charge of a battery that may be traversed in connection with the embodiments described herein;

FIG. 6 is a schematic view of resistive elements associated with a battery; and

FIG. 7 is a flowchart depicting a method for correcting a state of charge value that may be executed in connection with the method depicted in FIG. 5.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

An understanding of embodiments detailed herein is aided by an understanding of several terms. As used herein, the discharge rate (C) is a measurement of a discharge rate at which the battery would be depleted in one hour. For example, a battery rated at 1 Ah provides 1 Amp for one hour if discharged at 1C. The same battery discharged at 0.5C would provide 500 mA for two hours. The full charge capacity (FCC) is the total amount of charge that can be extracted from a fully charged battery. More specifically, FCC is defined as the amount that can be extracted from the battery at a discharge current that is less than (1/20)*C. FCC changes with age and cycle life of the battery. Remaining capacity (RC) is the amount of charge remaining in the battery at its current state. After a full charge, RC=FCC. Similar to FCC, it is assumed that the discharge current is less than (1/20)*C. Unusable capacity is the battery capacity that cannot be used due to the voltage drop across the battery impedance reducing the battery voltage below the failure voltage. Unusable capacity (UUC) is a function of the discharging current, and the remaining usable capacity (RUC) is the remaining capacity (RC) minus the unusable capacity (UUC). And as used herein, Rbatt is the internal resistance of the battery.

The state of charge (SOC) is the ratio of the remaining capacity to the total capacity (SOC=RC/FCC). When reported to the end user, it is useful to include UUC in the calculation of SOC: SOC=RUC/UC=(RC−UUC)/(FCC−UUC). A battery monitoring system (BMS) is a system, which reports the state of charge (SOC). Open circuit voltage (OCV) is the battery voltage at steady-state, near zero (e.g., less than C/20), current. It should be noted that, in many instances, battery voltage takes 5 to 30 minutes to settle to open circuit voltage (OCV) after the battery is unloaded.

The state of charge (SOC) is the ratio of the remaining capacity to the total capacity (SOC=RC/FCC). When reported to the end user, it is useful to include UUC in the calculation of SOC: SOC=RUC/UC=(RC−UUC)/(FCC−UUC), where UC is the usable charge of the battery: UC=FCC−UUC. A battery monitoring system (BMS) is a system, which reports the state of charge (SOC). Open circuit voltage (OCV) is the battery voltage at steady-state, near zero (e.g., less than C/20), current. It should be noted that, in many instances, battery voltage takes 5 to 30 minutes to settle to open circuit voltage (OCV) after the battery is unloaded.

Several embodiments disclosed herein improve the indications of how much battery capacity is available by reducing the state-of-charge (SOC) error that is prone to occur in existing systems at the end of battery life. As discussed above, it is very undesirable for a mobile communication device to go into under voltage lockout (UVLO) due to an SOC error. And as discussed further herein, embodiments disclosed further herein utilize knowledge of battery voltage and current to compensate for SOC error to provide more accurate status data to the user, to shutdown the mobile device at the appropriate point, and keep the system out of UVLO until it is actually necessary to do so.

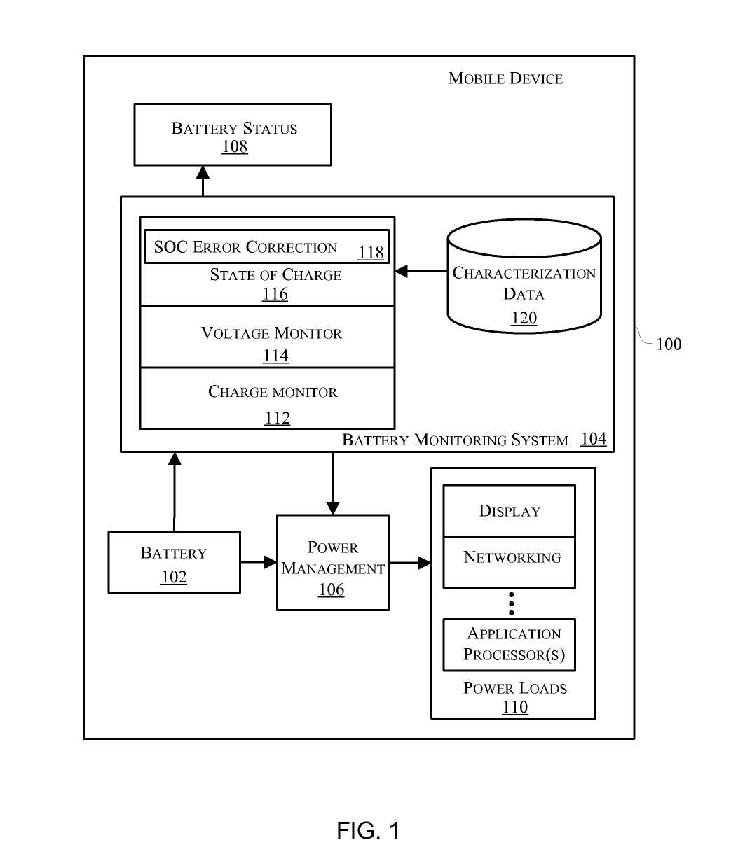

Referring first to FIG. 1, it is a block diagram of a mobile device 100 in which embodiments described herein may be realized. As shown, the mobile device 100 includes a battery 102 that is coupled to a battery monitoring system 104 and a power management component 106. In this embodiment, the battery monitoring system 104 is in communication with a battery status indicator 108, and the power management component 106 is coupled to a collection of power loads 110. As depicted, the battery monitoring system 104 includes a charge monitor 112, a voltage measurement component 114, and a state of charge component 116, which includes an SOC error correction component 118, and as shown, the state of charge component 116 is coupled to characterization data 120. The mobile device 100 may be realized by any of a variety of types of mobile devices including smartphones, netbooks, gaming devices, tablets, netbooks, PDAs, and laptop computers.

It should be recognized that FIG. 1 is primarily intended to depict functions of the mobile communication device 100 for purposes of describing the operation of various potential embodiments (and associated methods) that are described further herein. FIG. 1 is not intended to depict discrete identifiable hardware or software components. For example, the depicted components of the battery monitoring system 104 may be realized by hardware, software, or as discussed further herein, a combination of both hardware and software. By way of further example, the underlying constructs to effectuate the battery monitoring system 104 are also part of the collection of power loads 110 (i.e., the battery monitoring system 104 also draws power itself).

The battery 102 generally functions as the power source for the mobile device 100, and it is not limited to any particular chemistry or mechanical configuration, but rechargeable lithium-ion-type batteries are utilized to realize the battery 102 in many embodiments. As one of ordinary skill in the art will appreciate, the mobile device 100 also includes charging components (to charge the battery 102) that are not depicted in FIG. 1 for clarity.

The battery monitoring system 104 generally operates to provide an indication of the state of charge remaining in the battery 102. As shown, the state of charge information is utilized by the battery status indicator 108 to provide the user an indication of the remaining charge in the battery 102, and in addition, state of charge information is provided to the power management component 106, which generally controls the application of power to the various power loads 110 that may include a display, networking components (e.g., WiFi and Bluetooth components), processors, audio transducers, etc). For example, the power management component 106 may remove or reduce the power that is applied to particular loads (e.g., GPS, WiFi, NFC components, etc.) to prevent the mobile device 100 from going into under voltage lockout or simply to decrease a rate of battery discharge according to one or more parameters (e.g., default and/or user configurable parameters).

Although not required, the battery status indicator 108 may be realized by a service-level software component in connection with a display, among other components of the mobile device 100 that are known to those of skill in the art, to provide a graphical indication of a state of charge of the battery 102.

In this embodiment, the state of charge component 116 of the battery monitoring system 104 utilizes an indication of the battery voltage provided by the voltage monitor 114 and a coulomb count provided by the charge monitor 112 in connection with the characterization data 120 to arrive at a state of charge estimate. As discussed further herein, when the load on the battery 102 is at a steady state and below a threshold level (e.g., less than C/20), the battery 102 is considered to be in an open-circuit state, and when in this state, the open circuit voltage (OCV) of the battery 102 provides an accurate indication of the SOC of the battery based upon known data (stored within the characterization data 120) that relates OCV to the state of charge the battery 102.

This SOC-versus-OCV data may be generated well in advance of a user receiving the mobile device 100 by characterizing the battery 102 with a battery profile/calibration system under a variety of conditions (e.g., temperatures and charge-cycles) to obtain SOC-versus-OCV data for the battery 102. Those of ordinary skill in the art are familiar with systems that operate as a source and load on a battery to generate such battery profiles. In the embodiment depicted in FIG. 1, this battery-characterization data is stored among other data in the characterization data 120. As discussed further herein, in addition to SOC-versus-OCV battery data, the characterization data 120 may also include battery resistance data and data that characterizes resistive elements associated with the battery 102 that may reside on a PCB board of the mobile device 100.

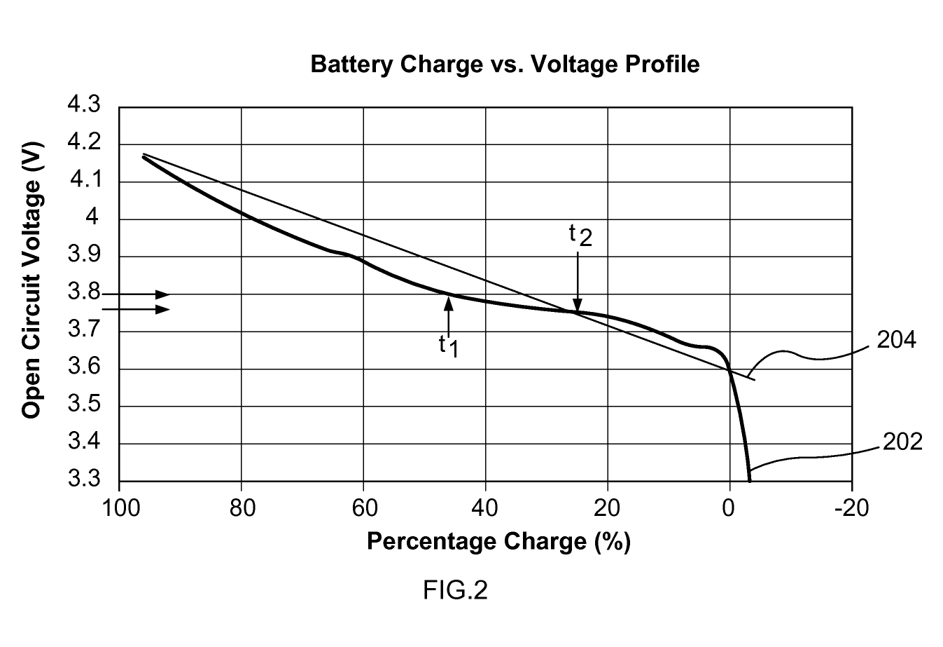

Referring to FIG. 2, shown is an exemplary battery profile curve 202 that maps OCV values to corresponding SOC values. As discussed, when an open circuit voltage measurement is possible, then battery curve 202 enables the SOC of the battery 102 to be accurately determined. As a consequence, in many embodiments, when an open circuit event occurs (e.g., the battery is in a substantially open circuit state), a voltage of the battery 102 is obtained.

Although existing battery monitoring systems utilize battery curves, these existing systems do not have satisfactory mechanisms or methods to compensate for power-on battery open circuit voltage (OCV) measurement error in an initial SOC estimate nor do they adequately compensate for accumulated Coulomb counter error. In a situation, for example, where the power-on OCV measurement is in the very flat portion of the battery curve (e.g., between t1 and t2) and/or the battery is not well represented by the curve 202, the initial SOC value can be very inaccurate. And if the mobile device 100 is in a high-load state for a long period of time, there is no chance for an updated OCV to correct the error, and the problem is further complicated by the fact that batteries may have two time constants, with the second time constant being very long (e.g., tens of minutes), which means the battery 102 may have to be substantially unloaded for several minutes before an accurate OCV reading may be obtained.

As shown in FIG. 2 for example, the actual battery curve 202 is non-linear and includes a relatively flat portion between points t1 and t2, which is a significant departure from the characteristics of the ideal, linear representation 204 of the remaining capacity in a battery. Thus, in reality, the remaining battery capacity represented by the actual battery curve 202 is non-linear and prone to being unreliable. Between points t1 (at about 45% of full charge), and t2 (at about 25% of full charge) for example, an error of about 0.06 Volts in OCV corresponds to an SOC error of about 20%. As a consequence, a small error in the assumed OCV results in a large error with respect to the state of charge reported to the user by the battery status indicator, and potentially undesirable operation by the power management component 106 (e.g., the power management component 106 may prematurely initiate under voltage lock out).

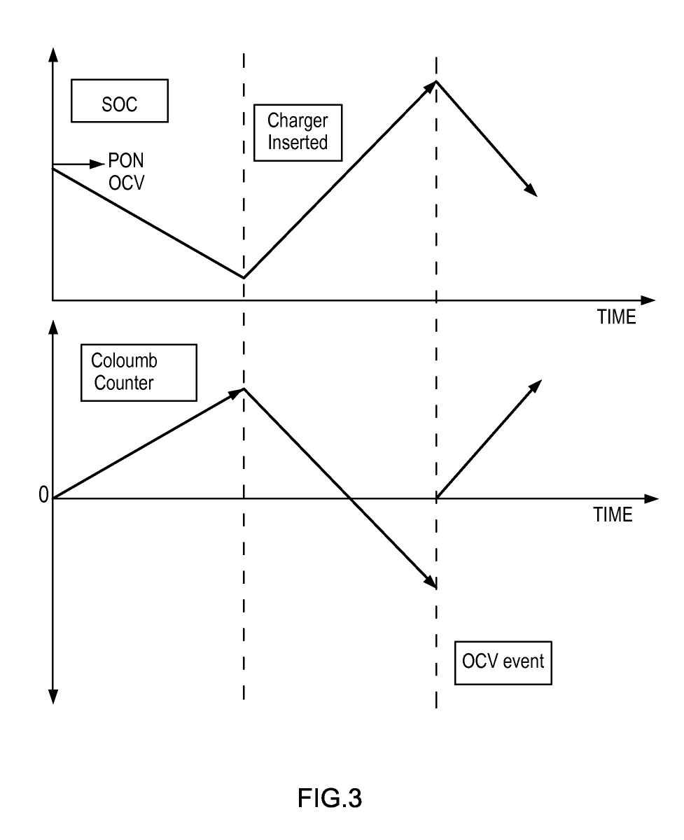

In an exemplary course of operation, as shown in FIG. 3, when the mobile device 100 is initially booted up, a power-on (PON) OCV measurement is made with the voltage monitor 114 and the state of charge component 116 accesses battery-characterization data from the characterization data 120 to map the measured OCV value to an SOC value in order to obtain a relatively accurate state of charge value on the battery curve. As shown in FIG. 3, after the OCV measurement is obtained, the battery 102 in this example is loaded (i.e., one or more power loads 110 are drawing current) so that an OCV measurement cannot be obtained, and as a consequence, the state of charge component 116 estimates the state of charge of the battery 102 based upon the charge that is removed, or added to, the battery 102. More specifically, the charge monitor 112 provides an indication of the charge that is being drawn from, or being added to, the battery 102, and the state of charge component 116 tracks the total amount of charge that is removed from and added to the battery 102 as depicted in the bottom graph. As shown, the Coulomb count goes up as charge is removed and goes down as charge is added to the battery 102 with a battery charger.

When the mobile device 100 again experiences an open circuit event (e.g., it reboots or goes into a sleep or standby mode), an OCV measurement is made again and the data represented by the battery curve 102 is accessed again to map the OCV value to a corresponding SOC value to obtain a substantially accurate indication of the status of the state of charge of the battery 102.

Problematically, during normal use mobile devices such as the mobile device 100 will, more often than not, be drawing too much current from the battery 102 to obtain an OCV measurement. For example, even when a user is not actively engaged with the mobile device 100, the mobile device 100 may be carrying out functions such as updating email, maintaining contact with cellular networks, looking for WiFi networks, maintaining Bluetooth connectivity, etc. As a consequence, the mobile device 100 often does not have the benefit of obtaining frequent OCV measurements, and as discussed above, the SOC calculations are prone to ongoing and potentially increasing errors over time.

As a consequence, in many embodiments, the typical SOC calculation performed under loaded conditions (that relies upon Coulomb counting after intermittent, unpredictable acquisition of OCV measurements) is augmented with state of charge corrections made by the SOC error correction component 118, which utilizes periodic and simultaneous monitoring of battery voltage and current, along with information about battery-related resistance, to compensate for SOC errors. In addition, one or more techniques disclosed further herein regulate a rate of SOC correction based upon the how much charge remains in the battery, aspects of the battery curve (e.g., a slope) in proximity to the approximate state of charge, and the amount of load the battery 102 is driving.

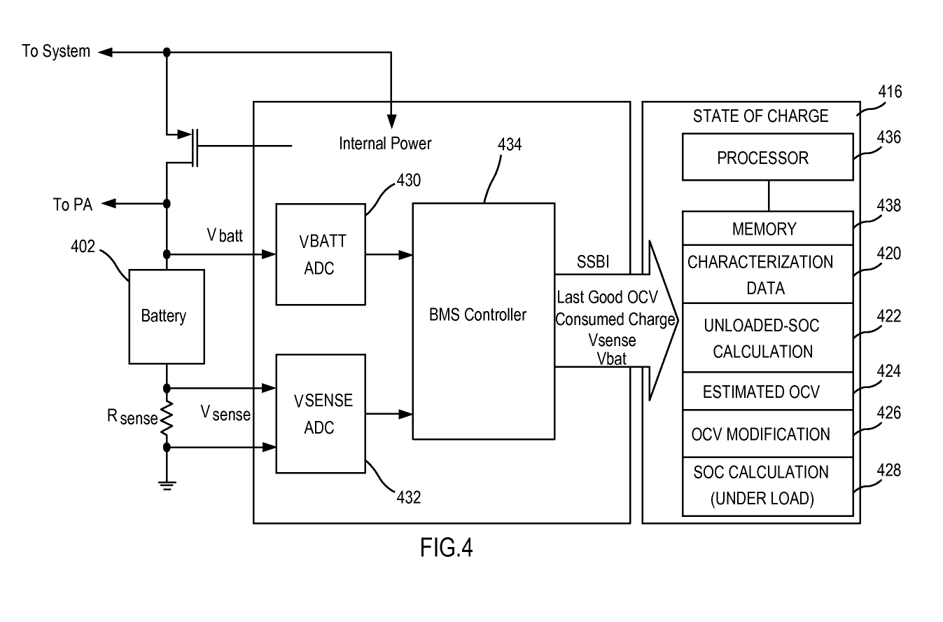

Referring to FIG. 4, shown is a block diagram of an exemplary embodiment of a battery monitoring system (e.g., one exemplary embodiment of the battery monitoring system 104), which is realized by a combination hardware and software components. As shown, in this embodiment indications of battery voltage and battery current are provided, in part, by Vbatt-ADC 430 and a Vsense-ADC 432, respectively. More specifically, the Vbatt-ADC 430 component monitors and converts an analog signal indicative of the battery voltage, Vbatt, to a digital representation of the battery voltage. And the Vsense-ADC 432 component monitors and converts an analog signal indicative of the voltage, Vsense, across a resistor, Rsense (e.g., 10 to 25 milliohms), to a digital representation of Vsense to provide an output to a BMS controller 434 that is indicative of the charge that the battery 402 provides and receives.

The BMS controller 434 in this embodiment manages the Vbatt-ADC 430 and Vsense-ADC 432 components and also controls measurement frequency, averaging, Coulomb counting, and CC resets. In addition, in this embodiment the BMS controller 434 provides a last, “good” OCV value; a consumed charge value; a value indicative of Vsense; and a value indicative of Vbatt. Although not required, the BMS controller 434 may be realized by hardware that implements a finite state machine, which functions without software control.

The state of charge component 416 depicted in FIG. 4 is an exemplary embodiment of the state of charge component 116 described with reference to FIG. 1. In this embodiment, the state of charge component 116 is realized by a processor 436 in connection with processor-executable instructions that reside in a non-transitory memory 438 to effectuate the state of charge calculation and correction. It should be recognized that the architecture of battery monitoring system depicted in FIG. 4 is merely one potential embodiment of the battery monitoring system 104 depicted in FIG. 1, and that other embodiments may also be utilized.

In general, the state of charge component 416 depicted in FIG. 4 calculates the SOC using raw data from the BMS controller 434, and may execute the SOC calculation when requested by a host (e.g., the battery status indicator 108 or power management component 106) or it may periodically calculate SOC and notify the host at specified SOC thresholds. To improve accuracy, the state of charge component 416 may periodically perform temperature corrections based upon known relationship between temperature and Vbatt, which may be characterized as temperature coefficients in characterization data 120, 420. In addition, the state of charge component 416 may store and utilize other specific data in the characterization data 420 that may include battery curve data (e.g., OCV-versus-SOC data); battery resistance; battery aging; temperature coefficients, and BMS settings. In addition, it may handle “special cases” such as learning cycle and initialization.

The estimated OCV component 424, the OCV modification component 426, and the SOC calculation 428 component collectively function as the SOC error correction component 118 described with reference to FIG. 1, but it should be recognized that the depiction of these components is intended to facilitate a description of functions of embodiments described herein, and when realized, these components may or may not be implemented as discrete software components.

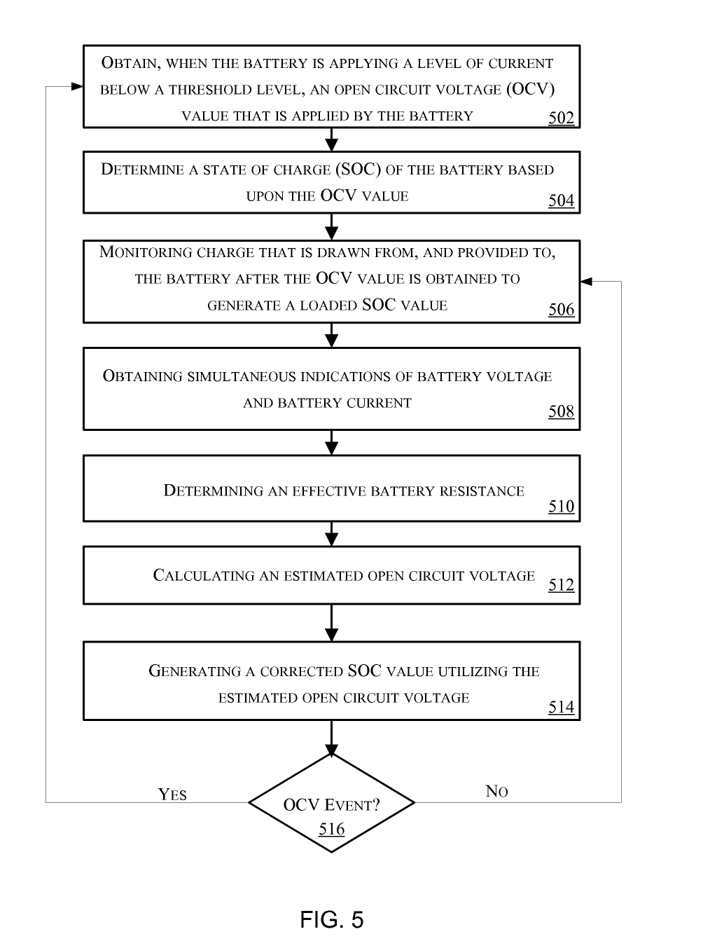

While referring to FIGS. 1 and 4, simultaneous reference is made to FIG. 5, which is a flowchart depicting aspects of an SOC calculation and correction method utilized in connection with the embodiments disclosed in FIGS. 1 and 4, among others. By reducing the SOC error, especially near the end of battery life, power management techniques (e.g., effectuated by the power management component 106) may be more effectively utilized at one or more appropriate times to reduce or substantially eliminate the load imparted by the mobile device 100 upon the battery 102 to defer or prevent the mobile device 100 from entering under voltage lockout.

As shown in FIG. 5, during the relatively rare occasion when the battery 102, 402 is applying a level of current that is below a threshold level (e.g., 8 mA), an actual open circuit voltage (OCV) value that is applied by the battery 102, 402 is obtained (Block 502), and a state of charge of the battery 102, 402 is determined by the unloaded-SOC component 422 based upon the actual OCV value (Block 504). As discussed above, a battery curve (e.g., the battery curve 202) stored in the characterization data 120, 420 will provide a relatively accurate indication of the SOC of the battery 102, 402 when an accurate OCV value is obtainable (e.g., when the battery is unloaded or substantially unloaded), but when the battery 102, 402 is loaded by one or more of the many power loads 110 of the mobile device 100, the battery 102 is no longer in an open circuit state. Although 8 mA is utilized in many implementations as a current threshold, it should be recognized that other current levels may be utilized as a threshold value if the voltage measurement obtained maps to a state of charge value on the battery curve 202 that is accurate within an acceptable tolerance.

As a consequence, after the OCV value is obtained (Block 502), when charge is being drawn from the battery 102, 402, or being provided to the battery 102, 402 by a charger, the charge is monitored and used to generate a loaded SOC value (Block 506). In many embodiments, after an OCV event occurs (e.g., reboot or a period of non-use), a timer may be used to keep track of time since the OCV measurement, and every 20 seconds thereafter, the change in Coulomb count (ΔCC_mAh) is determined in connection with the change in time (Δtime_s) since the last SOC calculation at Block 504 that was based upon an OCV measurement at Block 502. Based upon this Coulomb count and change in time, an average current (Ibat_avg) is calculated each time the loaded SOC value is determined (Block 506) using a moving average of a number of samples (e.g., 16 samples), where a sample (I) is calculated as follows:

Iavg=CC_mAh/(Δtime_{—}s*3600 h/s) (1)

During a first iteration of Blocks 506-514, when Δtime_s=0, instantaneous current may be utilized, and when charging, 300 mA may be used as the sample current to keep UUC at nominal value. The average battery current Ibat_avg is then calculated as:

$$Ibat\_avg = \frac{{\sum }_{0}^{n - 1} I}{n} \qquad ( 2 )$$

Where n is a maximum of 16.

The loaded SOC value determined at Block 506 may be calculated using UUC as follows:

$$SoC = \frac{Lookup ( OCV ) * FCC - \frac{CC}{{R}_{sense} } - UUC}{FCC - UUC} \qquad ( 3 )$$

And UUC may be calculated as:

UUC=FCC*Lookup(R_{batt}_{_{—}}ₜₑᵣₘ*I_{bat}_{_{—}}_{avg}+V_{Cut}_{_{—}}_{off}) (4)

Where FCC is a lookup value, and Vcut-off is a device setting for loaded shut-down voltage (typically 3.2 to 3.4V as determined by a mobile device manufacturer). The Rbatt_term in Equation 4 should not be the value at the current location in the SoC, but should be the “termination Rbatt,” or the battery resistance at the point where the UUC value maps to the SOC curve. A relatively easy way to determine “termination Rbatt” is to find a crossover value for the UUC voltage (=R_{batt}_{_{—}}ₜₑᵣₘ*I_{avg}+V_{cutoff}) and OCV when plugging in values Rbat for different SOC points.

Table 1 below provides an example using Vcutoff=3.4V and Iavg=1 A. Iavg may be the average current over 5 minutes, and may be created using 16 samples of 20-second Coulomb counter difference values, which are converted to current. To avoid UUC jumps when going from charging to discharging, the 20 s values for Iavg may be set to 300 mA when charging. When Iavg is going through large changes, UUC changes may be limited to 1% every 20 seconds.

TABLE 1

| | Rbat | OCV | Vuuc | | |
|---|---|---|---|---|---|
| | (from | (from | (calculated with | OCV − | |
| SOC | table) | table) | Rbat from table) | Vuuc | Comments |
| 30 | 0.1539 | 3761 | 3553.9 | 207.1 | |
| 25 | 0.16074 | 3727 | 3560.74 | 166.26 | |
| 20 | 0.19836 | 3696 | 3598.36 | 97.64 | |
| 15 | 0.24282 | 3669 | 3642.82 | 26.18 | Linearly |
| 10 | 0.25479 | 3593 | 3654.79 | −61.79 | interpolate |
| | | | | | Rbat between |
| | | | | | these 2 values |
| 9 | 0.27018 | 3567 | 3670.18 | −103.18 | |
| 8 | 0.28557 | 3540 | 3685.57 | −145.57 | |
| 7 | 0.30267 | 3514 | 3702.67 | −188.67 | |
| 6 | 0.32148 | 3474 | 3721.48 | −247.48 | |
| 5 | 0.34884 | 3437 | 3748.84 | −311.84 | |
| 4 | 0.3933 | 3397 | 3793.3 | −396.3 | |
| 3 | 0.47367 | 3347 | 3873.67 | −526.67 | |
| 2 | 0.62586 | 3280 | 4025.86 | −745.86 | |
| 1 | 2.60775 | 3183 | 6007.75 | −2824.75 | |

Addition details of exemplary approaches to determining state of charge are described in U.S. patent application Ser. No. 13/357,824 filed on Jan. 25, 2012 entitled “Battery Monitoring Circuit” which is commonly owned and assigned and is hereby incorporated by reference in its entirety.

As discussed above, merely relying on charge monitoring (Block 506) after the battery 102, 402 is loaded (i.e., after the OCV and SOC values are obtained in Blocks 502 and 504) to provide an updated, loaded SOC value does not correct for errors that occur when the OCV value is obtained at Block 502. It is also worth reiterating that during Block 502, the current being provided by the battery 102, 402 is ideally as low as possible, and as a consequence, current and voltage of the battery 102, 402 are typically not measured at the same time at Block 502.

In contrast, several embodiments disclosed herein obtain substantially simultaneous indications of battery voltage and battery current (Block 508) when the battery 102 is loaded, and this information is utilized by the estimated OCV component 424 in connection with an effective battery resistance value (Block 510) to arrive at an estimated OCV value (Block 512). Although the battery 102, 402 may be drawing a substantial amount of current (i.e., the battery is loaded and drawing a level of current that is above the threshold value (e.g., 8 mA)), the estimated OCV value is an indication of what the open circuit voltage of the battery 102 would be if the battery 102 were substantially unloaded (e.g., the current being drawn from the battery 102 were below the threshold value).

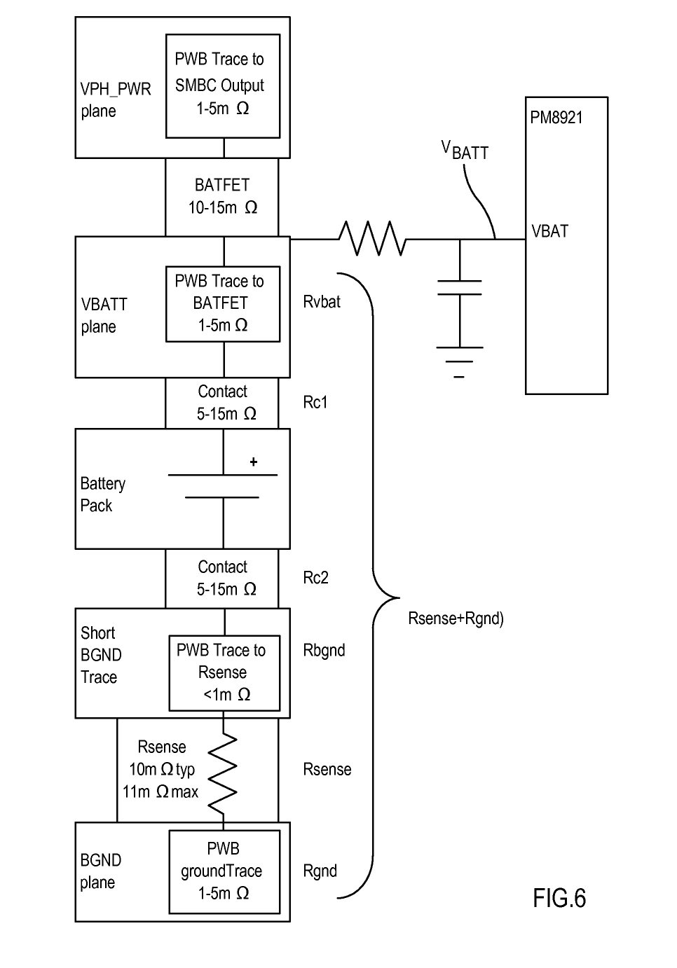

Referring briefly to FIG. 6, internal resistance of the battery (Rbat) may be obtained from a lookup table in the characterization data 120, 520, but the battery voltage is measured at the node Vbatt, so there is additional battery-related resistance, Rconn, depicted in FIG. 6 as (Rvbat+Rc1+Rc2+Rbgnd+Rsense+Rgnd) added to Rbat to obtain the effective battery resistance Rbat_eff. The value of Rconn may also be stored in the characterization data 102, 502. As shown in FIG. 4, the voltage across Rsense, also referred to as Vsense, is converted to a current value that, and OCVest is calculated as Vbat+Ibat*Rbat_eff.

In some embodiments, the BMS controller 434 operates in multiple modes. For example, the BMS controller 434 may operate in an autonomous mode during the operation depicted by Blocks 502-506, and then may be placed (e.g., when prompted by the state of charge component 416) into an “override mode” when obtaining the simultaneous voltage and current readings at Block 508. But it is certainly contemplated that other embodiments of the BMS controller 434 may be designed to autonomously receive simultaneous voltage and current readings (Block 508).

As shown in FIG. 5, in general, the estimated OCV value is utilized to correct errors in the loaded SOC value (Block 514) until there is an OCV event (Block 516) when the battery current is low enough, for a substantial amount of time, to obtain another OCV value (Block 502). More specifically, the battery current may be monitored on an ongoing basis for an indication that the battery 102, 402 is no longer loaded at Block 516, and that the state of the battery has settled so that another OCV value may be obtained with a reasonable confidence that any OCV value obtained in Block 502 will be a reliable representation of the SOC of the battery 102. And until there is an OCV event (Block 516), the steps described above with reference to Blocks 506-514 are repeated.

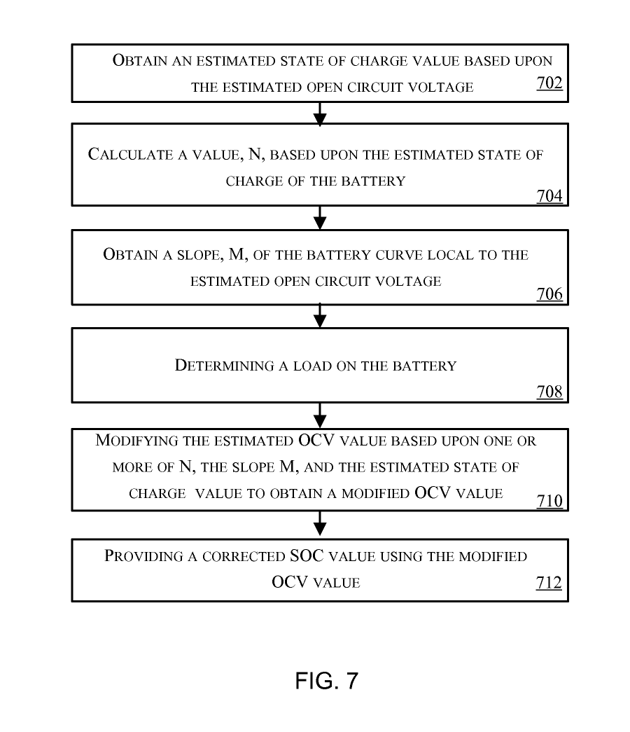

As discussed further in connection with FIG. 7, in many embodiments the estimated OCV value at Block 512 is utilized by the OCV modification component 426 to generate a modified OCV value, and the modified OCV value is utilized by the SOC calculation component 428 to generate a corrected SOC value. For example, the modified OCV value may be used in Equation 3 to calculate an estimated SOC value. In these embodiments, after the first iteration of Blocks 506-514, the modified OCV value is utilized as a starting point as if it were an actual measured OCV. Moreover, the modification of the OCV value may be controlled based upon one or more factors including a slope of the battery curve proximate to the estimated OCV value, a percent of charge remaining in the battery 102, 402, and a level of the load on the battery 102, 402. In many implementations, the OCV modification component 426 may utilize a filter to reduce an error between a current OCV value and the estimated OCV. For example, an infinite impulse response (IIR) filter, weighted by SOC level, may be utilized to modify a current OCV value based upon the estimated OCV value.

Referring to FIG. 7, for example, it is a flowchart depicting steps that may be traversed in connection with generating a corrected SOC value (Block 514) based upon the estimated open circuit voltage (Block 512). In general, the method depicted in FIG. 7 depicts steps associated with a modification to the OCV value that is utilized in Equation 3 to calculate a new corrected SOC value. As shown, an estimated state of charge (SOCest) is initially obtained based upon the OCVest value that was determined at Block 512. The value of SOCest may be obtained by mapping the OCVest to a state of charge value on the battery profile curve for the battery 102, 402.

As shown in FIG. 7, a value, N, is then calculated based upon the estimated state of charge of the battery (Block 704). The value N is used as a weighting factor for IIR filtering, which generally affects how fast an initial OCV value (also referred to as a current OCV value) is changed to an updated OCV value. In some embodiments, N is a number of steps that are taken to reach the estimated OCV level, and N may be equal to min(200, max(1, SOCactual+SOCest+last_SOCest)). The value of N limits the amount of change at higher SOC values and allows more change at lower SOC values so that correction may be effectuated quicker when the battery is almost exhausted of charge. In other words, the value of N reduces a rate of correction early in the battery profile curve when the battery is nearly completely charged, but when the battery is almost out of charge it is important to reduce errors in the state of charge more quickly.

In some implementations, as expressed above, N may be 200 at full charge and decrease as the state-of-charge approaches zero percent. When the state-of-charge is very low, for example, the number of iterations of Blocks 506-514 may only be two iterations (e.g. 40 seconds when Blocks 506-514 are repeated every 20 seconds) to correct the state-of-charge.

As shown in FIG. 7, a slope, M, of the battery curve local to the OCVest value is obtained (Block 706). The relevance of the slope M to the modification of the OCV value may be more clearly appreciated with reference to FIG. 2. As shown in FIG. 2, the slope M of the exemplary battery curve 202 is greater at higher and lower state-of-charge values, and the slope M is smaller between t1 and t2. As discussed above, when the slope of the battery curve 202 is relatively flat (e.g., between t1 and t2), a small change in OCV can correspond to a dramatic change in the SOC mapping. As a consequence, ΔOCV is calculated so that when the OCV value is in a flat region (e.g., between t1 and t2) the ΔOCV value (discussed below) is a smaller value so the OCV value is modified less than it is at higher and lower state-of-charge values (e.g., outside of t1 and t2).

In addition to limiting changes to OCV based upon the state of charge (as indicated by N) and the slope, M, of the battery curve, the modification to OCV may also be limited as a function of the load on the battery 102, 402. As a consequence, a load on the battery is determined (Block 708). When the load is low, e.g., 100 to 200 mA, corrections to the state of charge need not be made as fast. In some instances, the maximum change that is made to OCV (ΔOCV_{MAX}) is equal to I_{AVG}*1 mΩ. This limitation functions as a clamp, and may help to prevent over corrections to the OCV value.

As shown, the estimated OCV value is modified based upon one or more of N, the slope M, and the load on the battery to obtain a modified OCV value (also referred to as an updated OCV value) (Block 710). In several embodiments, a ΔOCV value is determined, which is the amount the initial OCV value will be modified. This ΔOCV value may be calculated as: ΔOCV=M*(SOCest−SOC)/(N), where M=slope of battery profile curve near the OCVest point. In some implementations, if both the loaded SOC value and the estimated SOC value are outside the range of 25% to 45% of full charge, then OCV=OCV+ΔOCV. As shown, a corrected SOC value is then provided using the modified OCV value (Block 712). To prevent premature shutdown, if the corrected SOC value is substantially equal to zero and the SOCest value is greater than zero, the corrected SOC value is set to 1.

In many embodiments, the steps described with reference to Blocks 506-514 in FIG. 5 (and Blocks 702-712 in FIG. 7 detailing Block 514) are repeated when an updated SOC value is requested, but the modified OCV value (from Block 512) is utilized as an initial OCV value instead of the measured OCV value (from Block 502) until the BMS controller 434 generates a “good OCV” update, which is an OCV value obtained when the battery 102, 402 is substantially unloaded and has settled.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A method for determining a state of charge of a battery on a mobile device, the method comprising:
obtaining, when the battery is applying a level of current below a threshold level, an initial state of charge of the battery based upon a measured open circuit voltage value that is applied by the battery;
monitoring charge drawn from, and provided to, the battery from a time after the measured open circuit voltage value is obtained;
calculating a loaded state of charge value when the battery is loaded after the initial open circuit voltage value is obtained based upon the monitored charge;
calculating an estimated open circuit voltage for the battery based upon simultaneous measurements of battery voltage and battery current; and
generating a corrected state of charge value using the estimated open circuit voltage.

2. The method of claim 1, wherein generating a corrected state of charge value using the estimated open circuit voltage includes:
using the estimated open circuit voltage to modify the measured open circuit voltage, the modification of the measured open circuit voltage is based upon one or more of: an estimated state of charge corresponding to the estimated open circuit voltage, a slope of a battery curve of the battery at the estimated open circuit voltage, and a load on the battery.

3. The method of claim 1, including:
accessing characterization data stored on the mobile device to obtain a battery resistance value and a resistance of circuit board components of the mobile device between a terminal node where the open circuit voltage is measured and ground;
calculating an effective battery resistance that is equal to the sum of the battery resistance value and the resistance of the circuit board components; and
calculating the estimated open circuit voltage for the battery as a sum of a voltage at the node where the open circuit voltage is measured and a product of the battery current and the effective battery resistance.

4. The method of claim 1, including:
detecting an open circuit event; and
obtaining another open circuit measurement to obtain another initial state of charge of the battery based upon the measured open circuit value.

5. A device for determining a state of charge of a battery, the device comprising:
a voltage monitor component to provide an indication of a voltage of the battery;
a charge monitor component to provide an indication of charge drawn from, and provided to, the battery;
a collection of characterization data that includes battery data that defines a battery curve that maps open circuit voltage values of the battery to state of charge values for the battery;
a state of charge (SOC) component that obtains, using the characterization data, a state of charge value of the battery for a measured open circuit voltage (OCV) and estimates a loaded state of charge of the battery when the battery is loaded by adjusting the state of charge value based upon the charge drawn from, and provided to, the battery; and
an SOC error correction component that reduces errors in the loaded state of charge value using an estimated open circuit voltage that is calculated from simultaneous readings of the voltage and current of the battery.

6. The device of claim 5, wherein the SOC error correction component includes an OCV modification component that periodically modifies the estimated open circuit voltage while the battery is loaded to based upon one or more of: an estimated state of charge corresponding to the estimated open circuit voltage, a slope of a battery curve of the battery at the estimated open circuit voltage, and a load on the battery.

7. The device of claim 5, wherein the characterization data includes a battery resistance value and a resistance of circuit board components between a terminal node where the open circuit voltage is measured and ground, and the SOC error correction component:
calculates an effective battery resistance that is equal to the sum of the battery resistance value and the resistance of the circuit board components; and
calculates the estimated open circuit voltage for the battery as a sum of a voltage at the node where the open circuit voltage is measured and a product of the battery current and the effective battery resistance.

8. The device of claim 5, wherein the state of charge component obtains another open circuit measurement, in response to an open circuit event, to obtain another state of charge of the battery based upon the measured open circuit value.

9. The device of claim 5, wherein the voltage monitor and the charge monitor include hardware components and the state of charge component and the SOC error correction component include software components.

10. A device for determining a state of charge of a battery on a mobile device, the device comprising:
means for obtaining, when the battery is applying a level of current below a threshold level, an initial state of charge of the battery based upon a measured open circuit voltage value that is applied by the battery;
means for monitoring charge drawn from, and provided to, the battery from a time after the measured open circuit voltage value is obtained;
means for calculating a loaded state of charge value when the battery is loaded after the initial open circuit voltage value is obtained based upon the monitored charge;
means for calculating an estimated open circuit voltage for the battery based upon simultaneous measurements of battery voltage and battery current; and
means for generating a corrected state of charge value using the estimated open circuit voltage.

11. The device of claim 10, wherein the means for generating a corrected state of charge value using the estimated open circuit voltage includes:
means for using the estimated open circuit voltage to modify the measured open circuit voltage, the modification of the measured open circuit voltage is based upon one or more of: an estimated state of charge corresponding to the estimated open circuit voltage, a slope of a battery curve of the battery at the estimated open circuit voltage, and a load on the battery.

12. The device of claim 10, including:
means for accessing characterization data stored on the mobile device to obtain a battery resistance value and a resistance of circuit board components of the mobile device between a terminal node where the open circuit voltage is measured and ground;
means for calculating an effective battery resistance that is equal to the sum of the battery resistance value and the resistance of the circuit board components; and
means for calculating the estimated open circuit voltage for the battery as a sum of a voltage at the node where the open circuit voltage is measured and a product of the battery current and the effective battery resistance.

13. The device of claim 10, including:
means for detecting an open circuit event; and
means for obtaining another open circuit measurement to obtain another initial state of charge of the battery based upon the measured open circuit value.

14. A non-transitory, tangible computer readable storage medium, encoded with processor readable instructions to perform a method for determining a state of charge of a battery on a mobile device, the method comprising:
obtaining, when the battery is applying a level of current below a threshold level, an initial state of charge of the battery based upon a measured open circuit voltage value that is applied by the battery;
monitoring charge drawn from, and provided to, the battery from a time after the measured open circuit voltage value is obtained;
calculating a loaded state of charge value when the battery is loaded after the initial open circuit voltage value is obtained based upon the monitored charge;
calculating an estimated open circuit voltage for the battery based upon simultaneous measurements of battery voltage and battery current; and
generating a corrected state of charge value using the estimated open circuit voltage.

15. The non-transitory, tangible computer readable storage medium of claim 14, wherein generating a corrected state of charge value using the estimated open circuit voltage includes:
using the estimated open circuit voltage to modify the measured open circuit voltage, the modification of the measured open circuit voltage is based upon one or more of: an estimated state of charge corresponding to the estimated open circuit voltage, a slope of a battery curve of the battery at the estimated open circuit voltage, and a load on the battery.

16. The non-transitory, tangible computer readable storage medium of claim 14, the method including:
accessing characterization data stored on the mobile device to obtain a battery resistance value and a resistance of circuit board components of the mobile device between a terminal node where the open circuit voltage is measured and ground;
calculating an effective battery resistance that is equal to the sum of the battery resistance value and the resistance of the circuit board components; and
calculating the estimated open circuit voltage for the battery as a sum of a voltage at the node where the open circuit voltage is measured and a product of the battery current and the effective battery resistance.

17. The non-transitory, tangible computer readable storage medium of claim 14, the method including:
detecting an open circuit event; and
obtaining another open circuit measurement to obtain another initial state of charge of the battery based upon the measured open circuit value.
